(19) United States
(12) Patent Application Publication
(10) Pub. No.: US 2007/0057346 A1
(43) Pub. Date: Mar. 15, 2007

(54) Semiconductor device having ESD protection with fuse

(76) Inventors: Joo-Hern Lee, Seoul (KR); Hee-Soo Seol, Yongin-si (KR); Jae-Eun Jeon, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/431,026

(22) Filed: May 10, 2006

(30) Foreign Application Priority Data
Sep. 15, 2005 (KR) 2005-0086031

(51) Int. Cl. H01L 29/00

(52) U.S. Cl. 257/546

(57) ABSTRACT

A semiconductor device is provided having an electrostatic discharge (ESD) protection function. It includes a plurality of no-connection (NC) pads, each associated with a corresponding NC ball, and each connected to a corresponding internal circuit, an ESD protection circuit connected to each one of the plurality of NC pads, and a fuse located between each respective NC pad and its corresponding internal circuit.

### BACKGROUND OF THE INVENTION

1. Technical Field

Embodiments of the invention relate to semiconductor devices having an integral electrostatic discharge (EDS) protection function. More particularly, embodiments of the invention relate to semiconductor devices having an ESD protection circuit adapted to prevent an arch discharge from damaging internal semiconductor device elements and components.

This application claims the benefit of Korean Patent Application No. 10-2005-0086031 filed Sep. 15, 2005, the subject matter of which is hereby incorporated by reference in its entirety.

2. Discussion of Related Art

Generally speaking, CMOS type semiconductor devices, such as those commonly used as memory devices, must be protected from the adverse effects of the surrounding environment, including stray static electricity charges. That is, conventional semiconductor memory devices include logical elements and components adapted to operate at an internal voltage ranging from several to tens of volts. When a voltage greatly exceeding this range is applied to the pins of a semiconductor memory device the internal elements and components may become damaged. For example, contemporary semiconductor devices contain many conductive elements spaced apart from each other by insulators having thicknesses measured in angstroms. Such insulators are easily overwhelmed (e.g., burnt through) by high voltages. Such damage often results in two or more conductive elements being short-circuited. Alternatively, an internal component such as diode or transistor may be damaged by the application of high voltage. Such phenomena may be caused by the application of static electricity to the Input/Output (I/O) pins (e.g., pins adapted to receive data, control, address, and/or power signals) of a semiconductor device. The damage or destruction of voltage sensitive semiconductor device components by ESD is referred to as “electrostatic breakdown.”

The susceptibility of a semiconductor device to electrostatic breakdown is commonly evaluated by testing conducted after a semiconductor chip has been assembled. As conventionally configured, semiconductor devices include power supply pins (hereinafter, referred to as “power pins”) and signal I/O pins. Conductive pads are variously connected to these pin types.

FIG. 1 generically illustrates a conventional ESD protection circuit which includes an NC (no-connection) pad 10, an internal circuit 12 connected to NC pad 10 by a connection line, a first diode 14 connected between power supply voltage Vdd and the connection line, and a second diode 16 connected between the connection line and a power supply voltage Vss. NC pads are commonly formed as part of the semiconductor device package.

First diode 14 is a PMOS transistor comprising a commonly connected source and gate. Second diode 16 is an NMOS transistor comprising a commonly connected source and a gate.

When a static electricity derived voltage is directly applied to NC pad 10, it is faithfully discharged by diodes 14 and 16, which form, respectively, pull-up and pull-down transistors. However, other types of ESD may nonetheless cause damage to the semiconductor device. One of these other forms of ESD is called an arch discharge, and despite the presence of a conventional ESD protection circuit, arch discharges may damage pad structures, such as those associated with command pins, address pins, data input pins, and data output pins, as well as related internal circuits and components.

### SUMMARY OF THE INVENTION

Embodiments of the invention provide a semiconductor device having an ESD protection function adapted to protect the internal circuits and components of a semiconductor device from the effects of an arch discharge.

Thus, in one embodiment, the invention provides a semiconductor device having an electrostatic discharge (ESD) protection function and comprising; a plurality of no-connection (NC) pads, each associated with a corresponding NC ball, and each connected to a corresponding internal circuit, an ESD protection circuit connected to each one of the plurality of NC pads, and a fuse located between each respective NC pad and its corresponding internal circuit.

The semiconductor device may have a 128M×4 layout, wherein the plurality of NC balls comprises fourteen (14) NC balls, or a 64M×8 layout, wherein the plurality of NC balls comprises ten (10) NC balls.

In a related aspect, the ESD protection circuit may comprise a first diode connected between an NC pad and a power supply voltage Vdd, and a second diode connected between the NC pad and a power supply voltage Vss. The first diode may be a PMOS transistor comprising a commonly connected source and gate, and the second diode may be an NMOS transistor comprising a commonly connected source and gate.

In another embodiment, the invention provides a semiconductor device having an electrostatic discharge (ESD) protection function and comprising; a plurality of no-connection (NC) pads, each associated with a corresponding NC ball, and each connected to a corresponding internal circuit, first and second ESD protection circuits connected to each one of the plurality of NC pads, and a fuse located between each respective NC pad and its corresponding internal circuit.

Here again, the semiconductor device may have a 128M×4 layout, wherein the plurality of NC balls comprises fourteen (14) NC balls, or a 64M×8 layout, wherein the plurality of NC balls comprises ten (10) NC balls.

Also, the ESD protection circuit may comprise a first diode connected between an NC pad and a power supply voltage Vdd, and a second diode connected between the NC pad and a power supply voltage Vss. The first diode may be a PMOS transistor comprising a commonly connected source and gate, and the second diode may be an NMOS transistor comprising a commonly connected source and gate.

### BRIEF DESCRIPTION OF THE DRAWINGS

Several embodiments of the invention will described with reference to the attached drawings in which:

FIG. 1 illustrates a conventional ESD protection circuit;

FIG. 2 illustrates an ESD protection circuit according to an embodiment of the invention and comprising a fuse;

FIGS. 3A, 3B, and 3C illustrate exemplary ball description layouts for selected examples of a 512M DDR C-DIE 60FBGA semiconductor device according to embodiments of the invention;

FIG. 4 illustrates an exemplary internal circuit connection for an ESD protection circuit adapted for use with a 128M×4 semiconductor device shown in FIG. 3A; and

FIG. 5 illustrates an exemplary internal circuit connection for an ESD protection circuit adapted for use within a 64M×8 semiconductor device shown in FIG. 3B.

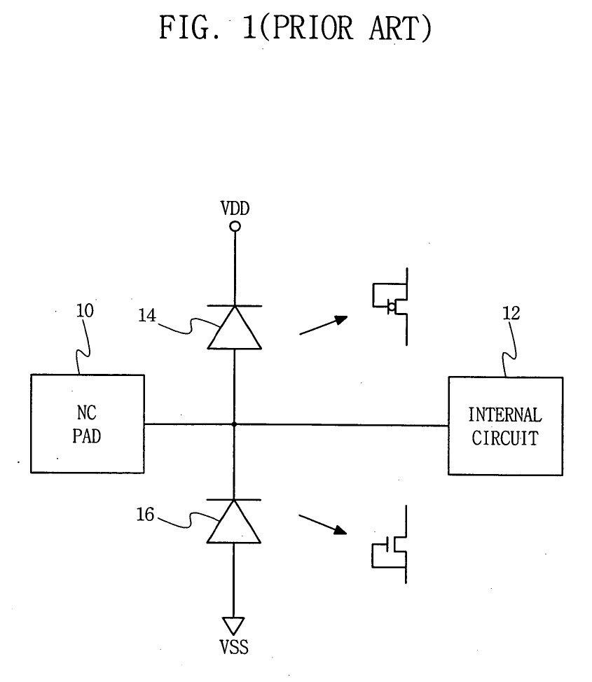

### DESCRIPTION OF THE EXEMPLARY EMBODIMENTS

The present invention will now be described in the context of several embodiments with reference to the accompanying drawings. However, the invention should not be construed as limited to only the embodiments set forth herein. Rather, these embodiments are presented as teaching examples. In the drawings, like numbers refer to like or similar elements.

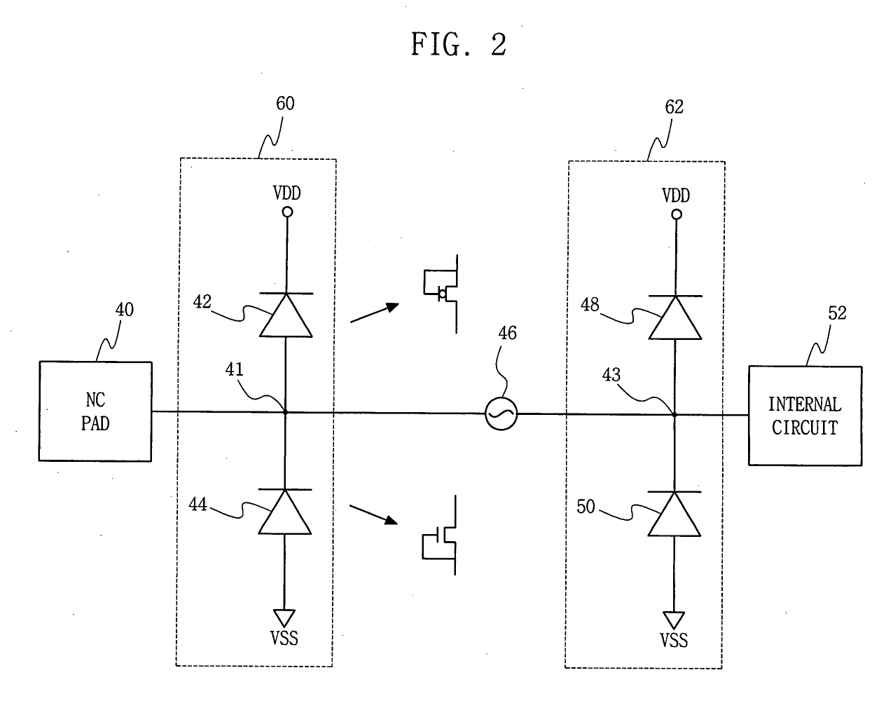

FIG. 2 illustrates an ESD protection circuit comprising a fuse according to an embodiment of the invention.

The static electricity discharge protection circuit comprises an NC pad 40, an internal circuit 52, a first diode 42 connected between NC pad 40 and a power supply voltage Vdd, a second diode 44 between NC pad 40 and a power supply voltage Vss, a third diode 48 connected between internal circuit 52 and Vdd, a fourth diode 50 connected between internal circuit 52 and Vss, and a fuse 46 between NC pad 40 and internal circuit 52.

NC pad 40 is connected to a connection node 41 located between first and second diodes 42 and 44. First and second diodes 42 and 44 are connected in series between Vdd and Vss. First diode 42 is a PMOS transistor comprising a commonly connected source and gate. Second diode 44 is an NMOS transistor comprising a commonly connected source and gate. In this configuration, first and second diodes 42 and 44 serve as a first ESD protection portion 60 adapted to safely discharge static electricity applied to NC pad 40.

Internal circuit 52 is connected to a connection node 43 between third and fourth diodes 48 and 50. Third and fourth diodes 48 and 50 are connected in series between Vdd and Vss. Third diode 48 is a PMOS transistor comprising a commonly connected source and gate. Fourth diode 50 is an NMOS transistor comprising a commonly connected source and gate. In this configuration, third and fourth diodes 48 and 50 serve a second ESD protection circuit 62 adapted to discharge static electricity applied to internal circuit 52 when fuse 46 is conductive (e.g., not cut or opened). Fuse 46 is connected between first ESD protection circuit 60 and second ESD protection circuit 62.

The application of the above embodiment will be further described in the context of two possible applications, e.g., a 128M×4 and a 64M×8 semiconductor memory device. In these specific examples, fuse 46 may be formed between an NC pad 40 and internal circuit 52, where NC pad 40 is bonded to a corresponding NC solder ball (or similar conductive structure). Where fuse 46 is “cut” (e.g., opened) using a laser, for example, and the corresponding NC ball has been damaged by static electricity, first ESD protection circuit 60 is nonetheless capable of safely discharging any applied static electricity. That is, if high voltage static electricity in the form of an arch discharge is generated within the conductive proximity of the corresponding NC ball and thus flows into NC pad 40, it will be safely discharged through first and second diodes 42 and 44.

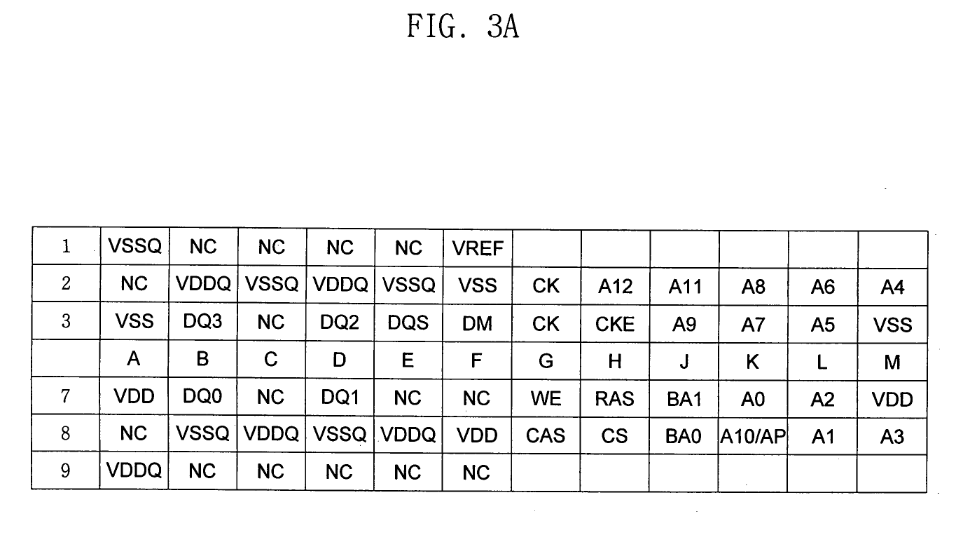

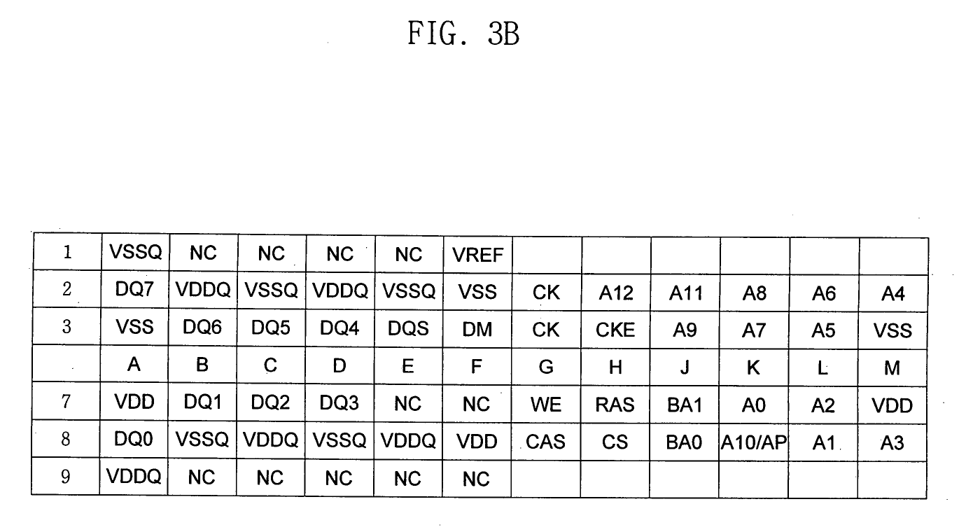

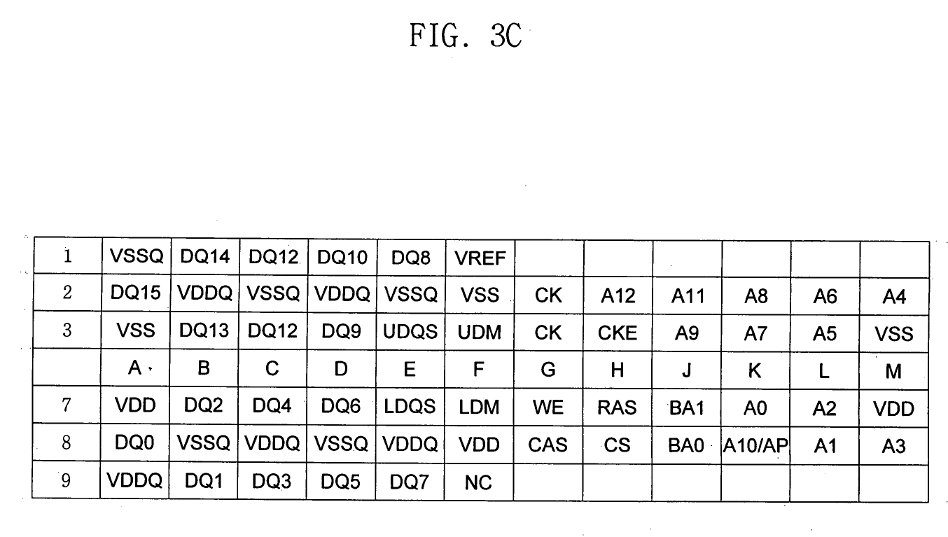

FIG. 3A illustrates the ball layout description for a 128M×4 512M DDR C-DIE 60FBGA. FIG. 3B illustrates the ball layout description for a 64M×8 512M DDR C-DIE 60FBGA. FIG. 3C illustrates the ball layout description for a 32M×16 512M DDR C-DIE 60FBGA.

As illustrated in these figures, the ball layout description for the 32M×16 semiconductor memory device are used as NC balls for the 64M×8 and/or the 28M×4 semiconductor memory device within the same chip depending on the number of the data input/output terminals present. In the 64M×8 semiconductor memory device, ten pads are associated with NC balls. In the 128M×4 semiconductor memory device, fourteen pads are associated with NC balls. Thus, the 128M×4 and 64M×8 semiconductor memory devices are particularly susceptible to damage caused by an arch discharge, compared with the 32M×16 semiconductor memory device.

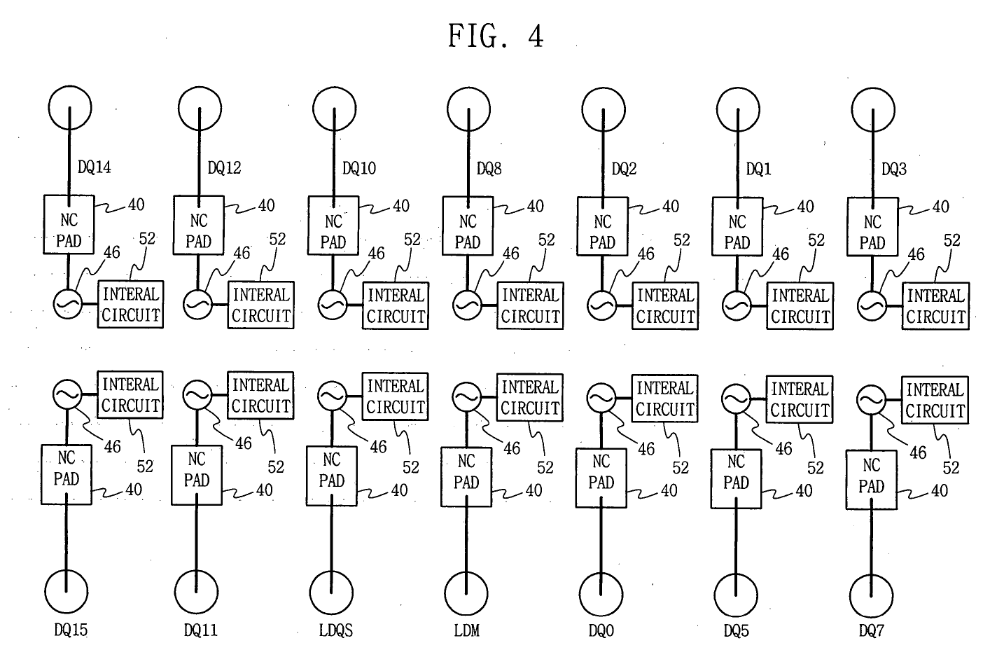

FIG. 4 illustrates an exemplary internal circuit connection for an ESD protection circuit for a 128M×4 semiconductor device, such as the one having a ball layout description shown in FIG. 3A.

Within this exemplary layout, data input/output terminals DQ0, DQ1, DQ2, DQ3, DQ5, DQ7, DQ8, DQ10, DQ11, DQ12, DQ14 and DQ15, row data strobe (LDQS) terminals, and row data mask (LDM) terminals are respectively connected to a plurality of NC pads 40. Each one of the plurality of NC pads 40 is respectively bonded to a corresponding one of a plurality of NC balls. A plurality of fuses 46 are respectively connected between the plurality of NC pads 40 and a plurality of internal circuits 52. In one embodiment, each one of the plurality of fuses 46 is cut. As shown in FIG. 4, the exemplary 128M×4 semiconductor memory device comprises fourteen (14) NC pads 40 associated one-for-one with a corresponding NC ball.

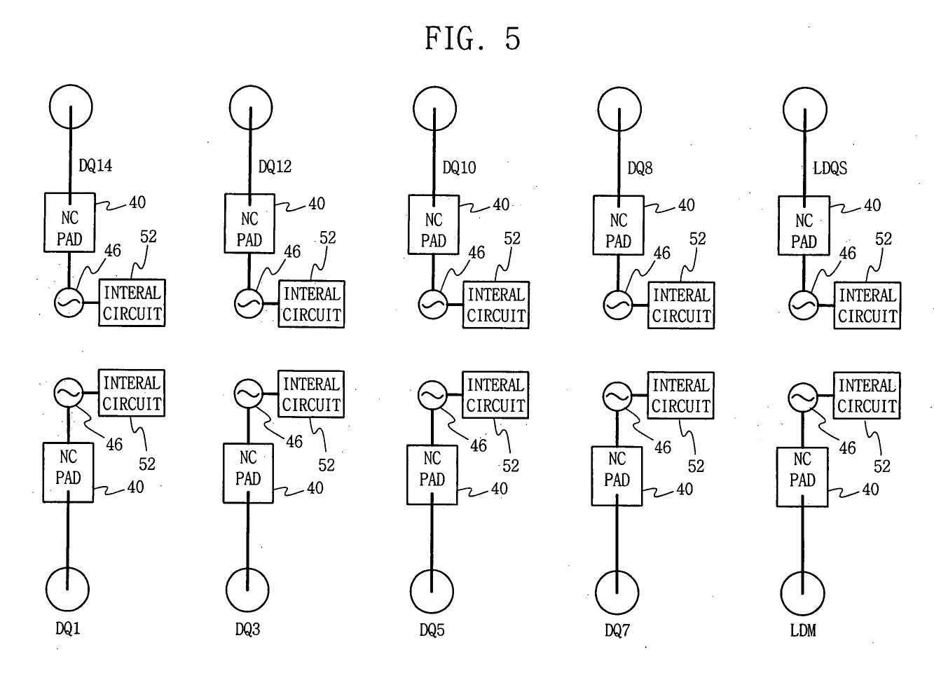

FIG. 5 illustrates an exemplary internal circuit connection for an ESD protection circuit for a 64M×8 semiconductor device, such as the one having a ball layout description shown in FIG. 3B.

Within this exemplary layout, data input/output terminals DQ1, DQ3, DQ5, DQ7, DQ8, DQ10, DQ12 and DQ14, a low data strobe (LDQS) terminal, and a low data mask (LDM) terminal are respectively connected to a plurality of NC pads 40. A plurality of fuses 46 are connected one-for-one to the plurality of NC pads 40. The plurality of fuses 46 provides electrical connection to a corresponding plurality of internal circuits 52. NC pads 40 are each respectively bonded to a corresponding NC ball. In one embodiment, the plurality of fuses 46 is cut. As shown in FIG. 5, the exemplary 64M×8 semiconductor memory device comprises ten (10) NC pads 40 associated one-for-one with a corresponding NC ball.

As described above, in a semiconductor device according to an embodiment of the invention, an NC pad having associated first and second ESD protection circuits is provided, and a fuse is also provided between the NC pad and an internal circuit. If an arch discharge is generated in conductive proximity to an NC ball associated with the NC pad, and even with the fuse having been cut, it is possible to protect the internal circuit from the over-voltage effects of the arch discharge using the ESD protection circuits.

Those of ordinary skill in the art will recognize that specific modifications may be made to the foregoing examples, and that embodiments of the invention may be applied to many different types of semiconductor devices. The foregoing embodiments are examples of a broader invention having a scope defined by the attached claims.

What is claimed is:

1. A semiconductor device having an electrostatic discharge (ESD) protection function, comprising:
a plurality of no-connection (NC) pads, each associated with a corresponding NC ball, and each connected to a corresponding internal circuit;
an ESD protection circuit connected to each one of the plurality of NC pads; and
a fuse located between each respective NC pad and its corresponding internal circuit.

2. The semiconductor device of claim 1 having a 128M×4 layout, and wherein the plurality of NC balls comprises fourteen (14) NC balls.

3. The semiconductor device of claim 1 having a 64M×8 layout, and wherein the plurality of NC balls comprises ten (10) NC balls.

4. The semiconductor device of claim 1, wherein the ESD protection circuit comprises:
a first diode connected between an NC pad and a power supply voltage Vdd; and
a second diode connected between the NC pad and a power supply voltage Vss.

5. The semiconductor device of claim 3, wherein the first diode is a PMOS transistor comprising a commonly connected source and gate, and the second diode is an NMOS transistor comprising a commonly connected source and gate.

6. The semiconductor device of claim 1, wherein the fuse is cut using a laser.

7. A semiconductor device having an electrostatic discharge (ESD) protection function, comprising:
a plurality of no-connection (NC) pads, each associated with a corresponding NC ball, and each connected to a corresponding internal circuit;
first and second ESD protection circuits connected to each one of the plurality of NC pads; and
a fuse located between each respective NC pad and its corresponding internal circuit.

8. The semiconductor device of claim 7, wherein the fuse is located between the first and second. ESD protection circuits.

9. The semiconductor device of claim 8 having a 128M×4 layout, and wherein the plurality of NC balls comprises fourteen (14) NC balls.

10. The semiconductor device of claim 8 having a 64M×8 layout, and wherein the plurality of NC balls comprises ten (10) NC balls.

11. The semiconductor device of claim 7, wherein each one of the first and second ESD protection circuits comprises:
a first diode connected between an NC pad and a power supply voltage Vdd; and
a second diode connected between the NC pad and a power supply voltage Vss.

12. The semiconductor device of claim 11, wherein the first diode is a PMOS transistor comprising a commonly connected source and gate, and the second diode is an NMOS transistor comprising a commonly connected source and gate.

13. The semiconductor device of claim 12, wherein the fuse is cut using a laser.
